(19) United States
(12) Patent Application Publication
(10) Pub. No.: US 2014/0374863 A1
(43) Pub. Date: Dec. 25, 2014

(54) IMAGE PICKUP APPARATUS, METHOD OF DESIGNING THE SAME, AND METHOD OF MANUFACTURING THE SAME

(71) Applicant: CANON KABUSHIKI KAISHA, Tokyo (JP)

(72) Inventor: Takumi Ogino, Koganei-shi (JP)

(21) Appl. No.: 14/305,224

(22) Filed: Jun. 16, 2014

(30) Foreign Application Priority Data
Jun. 21, 2013 (JP) 2013-131056

(51) Int. Cl. H01L 27/146; G06F 17/50

(52) U.S. Cl. CPC H01L 27/14625; G06F 17/5068; H01L 27/14685; H01L 27/14621
USPC 257/432; 716/110; 438/70

(57) ABSTRACT

An image pickup apparatus includes a plurality of types of pixels, each of which includes a conversion element configured to convert light into a charge and one of a plurality of types of filters configured to transmit light in different wavelength bands. A type of pixel of the plurality of types of pixels further includes a lightguide configured to guide light entering the pixel to the conversion element. Another type of pixel of the plurality of types of pixels includes no structure corresponding to the lightguide.

### BACKGROUND OF THE INVENTION

1. Field of the Invention

The present invention relates to an image pickup apparatus, a method of designing the same, and a method of manufacturing the same.

2. Description of the Related Art

In order to improve the sensitivity of an image pickup apparatus used for a digital camera or a camcorder, Japanese Patent Laid-Open No. 2009-272568 discloses an arrangement having a lightguide above a conversion element. When incident light is partially reflected by an interface of the lightguide and reaches the conversion element, the light collection efficiency of the conversion element improves. Japanese Patent Laid-Open No. 2011-258593 discloses a technique of setting the width or height of a lightguide for each of pixels designed to detect light in different wavelength bands to further improve sensitivity.

### SUMMARY OF THE INVENTION

In the image pickup apparatuses proposed in Japanese Patent Laid-Open Nos. 2009-272568 and 2011-258593, all types of pixels have lightguides. As will be described in detail below, however, providing a lightguide sometimes decreases the sensitivity of a pixel depending on light in a wavelength band as a detection target for the pixel. An aspect of the present invention provides a technique of further improving the sensitivity of a pixel in an image pickup apparatus including a plurality of types of pixels.

According to an aspect of the present invention, an image pickup apparatus includes a plurality of types of pixels, each of the plurality of types of pixels comprising a conversion element configured to convert light into a charge, and one of a plurality of types of filters configured to light in different wavelength bands, wherein a first type of pixel of the plurality of types of pixels further includes a lightguide configured to guide light entering the pixel to the conversion element, and a second type of pixel of the plurality of types of pixels includes no structure corresponding to the lightguide.

According to another aspect of the present invention, a method of designing an image pickup apparatus includes a plurality of types of pixels, each of the plurality of types of pixels comprising a conversion element configured to convert light into a charge, and one of a plurality of types of filters configured to transmit light in different wavelength bands, and the method comprising determining, for each of the plurality of types of pixels, whether an amount of light reaching the conversion element increases more when a lightguide which guides light entering the pixel to the conversion element is provided than when the lightguide is not provided.

Further features of the present invention will become apparent from the following description of exemplary embodiments (with reference to the attached drawings).

### BRIEF DESCRIPTION OF THE DRAWINGS

FIG. 1 is a schematic sectional view of an image pickup apparatus according to some embodiments of the present invention;

FIG. 2 is a layout of pixels of the image pickup apparatus according to some embodiments of the present invention;

FIGS. 3A and 3B are views for explaining light paths in pixels of the image pickup apparatus according to some embodiments of the present invention;

FIG. 4 is a graph for explaining the light collection efficiencies of pixels in the image pickup apparatus according to some embodiments of the present invention;

FIG. 5 is a graph for explaining the relationship between the refractive index and extinction coefficient of a lightguide in some embodiments of the present invention; and

FIGS. 6A and 6B are views for explaining a method of manufacturing an image pickup apparatus according to some embodiments of the present invention.

### DESCRIPTION OF THE EMBODIMENTS

Various embodiments of the present invention will be described below with reference the accompanying drawings. The same reference numerals throughout various embodiments denote the same elements, and a repetitive description will be omitted. In addition, the respective embodiments can be modified and combined, as needed.

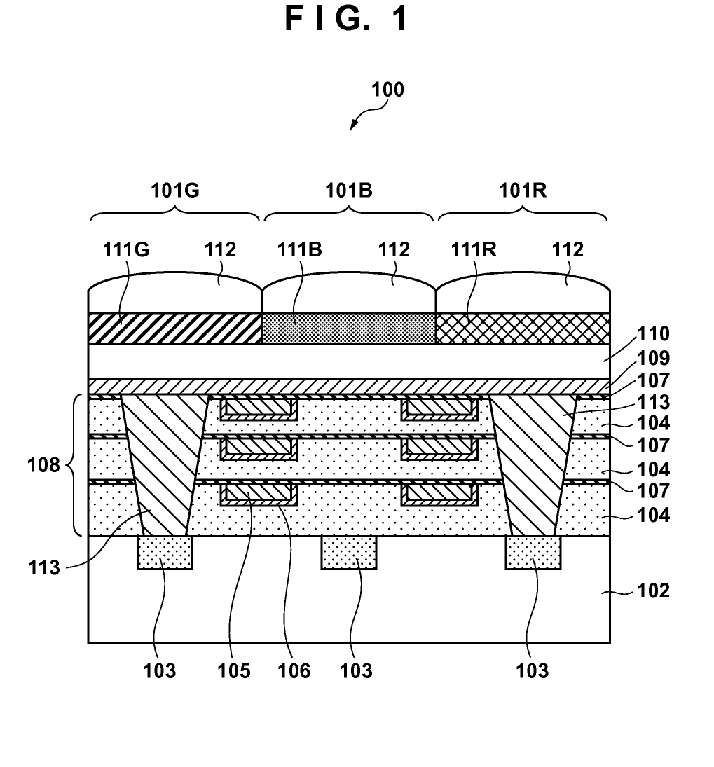

The structure of an image pickup apparatus 100 according to some embodiments of the present invention will be described with reference to FIG. 1. The image pickup apparatus 100 can be a solid-state image pickup apparatus. Elements other than the lightguides of the image pickup apparatus 100 may have any arrangement and can use existing arrangements. An example of such an arrangement will be simply described below. The image pickup apparatus 100 includes a plurality of pixels. FIG. 1 schematically shows cross-sections of three pixels 101B, 101G, and 101R. In the following description, the pixels 101B, 101G, and 101R will be collectively referred to as pixels 101.

Each pixel 101 can include a conversion element 103 formed in a semiconductor substrate 102. The conversion element 103 can be a photoelectric conversion element which converts light into charges. Light can include not only visible light but also infrared light and ultraviolet light. The adjacent conversion elements 103 are isolated from each other by an element isolation region. An interlayer dielectric film 104 can be provided on the semiconductor substrate 102. A wiring trench is formed in the interlayer dielectric film 104. A wiring pattern 105 formed from, for example, copper is provided in the wiring trench. A barrier metal layer 106 can be provided between the wiring pattern 105 and the interlayer dielectric film 104. An anti-diffusion layer 107 can be provided so as to cover the interlayer dielectric film 104 and the wiring pattern 105. A multilayer wiring layer 108 is formed by stacking a plurality of structures each including the interlayer dielectric film 104, the wiring pattern 105, the barrier metal layer 106, and the anti-diffusion layer 107. Referring to FIG. 1, the multilayer wiring layer 108 has a three-layer structure. However, the present invention is not limited to this.

A passivation film 109 as, for example, a silicon nitride film or a silicon oxynitride film is provided on the multilayer wiring layer 108, and a planarization resin layer 110 can be provided on the passivation film 109. A plurality of types of filters 111B, 111G, and 111R can be provided on the planarization resin layer 110. In the following description, the filters 111B, 111G, and 111R will be collectively referred to as filters 111. The pixel 101B is a pixel for detecting blue light. The filter 111B configured to transmit blue light can be provided for the pixel 101B. In this case, blue light is light in the wavelength band of 350 nm to 500 nm. The filter 111B selectively transmits light in this wavelength band. The pixel 101G is a pixel for detecting green light. The filter 111G configured to transmit green light can be provided for the pixel 101G. In this case, green light is light in the wavelength band of 450 nm to 650 nm. The filter 111G selectively transmits light in this wavelength band. The pixel 101R is a pixel for detecting red light. The filter 111R configured to transmit red light can be provided for the pixel 101R. In this case, red light is light in the wavelength band of 550 nm to 800 nm. The filter 111R selectively transmits light in this wavelength band. Microlenses 112 can be provided on the filters 111, respectively. Each microlens 112 condenses light entering the image pickup apparatus 100 to the corresponding conversion element 103. Bands of wavelengths transmitted by the plurality of types of filters 111B, 111G, and 111R may partially overlap with each other. Peak wavelengths of spectral transmittance of the plurality of types of filters 111B, 111G, and 111R may be different from each other. The image pickup apparatus 100 in FIG. 1 includes the microlenses 112. However, an image pickup apparatus according to other embodiments may not include the microlenses 112.

The pixel 101G for green light and the pixel 101R for red light can respectively include lightguides 113. The lightguide 113 is formed from a core member having a higher refractive index than a surrounding cladding member. The lightguides 113 guide the light transmitted through the microlenses 112 and the filters 111G and 111B to the conversion elements 103, respectively. Each lightguide 113 can be formed from, for example, silicon nitride, and each interlayer dielectric film 104 can be formed from, for example, silicon oxide. Since silicon nitride has a higher refractive index than silicon oxide, light entering each lightguide 113 can be reflected by the interface between the lightguide 113 and the corresponding interlayer dielectric film 104.

The pixel 101B for blue light has no structure corresponding to the lightguide 113. The interlayer dielectric films 104 can be provided in portions of the pixel 101B which correspond to positions, in other types of pixels, in which the lightguides 113 are provided. As will be described in detail below, depending on a wavelength band as a detection target for the pixel 101, the amount of light reaching the conversion element 103 can be larger when the lightguide 113 is not provided than when the lightguide 113 is provided. For this reason, in the image pickup apparatus 100, the lightguides 113 are respectively provided in the pixel 101G for green light and the pixel 101R for red light, whereas the lightguide 113 is not provided in the pixel 101B for blue light.

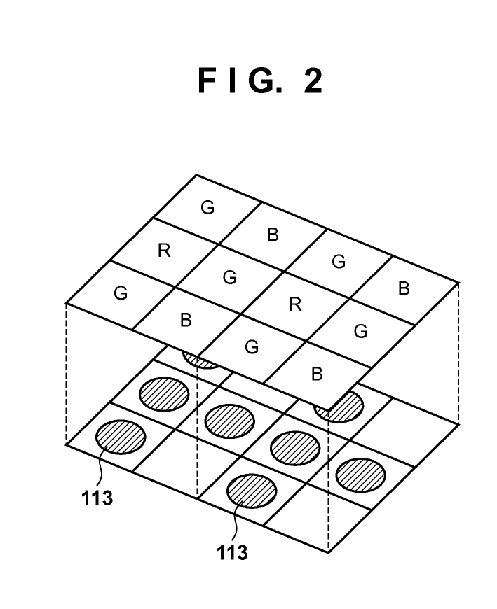

FIG. 1 shows a case in which the pixel 101G for green light, the pixel 101B for blue light, and the pixel 101R for red light are arrayed in a line. However, the pixels 101 of the image pickup apparatus 100 may have a Bayer arrangement like that shown in FIG. 2. In the arrangement of the pixels 101 shown in FIG. 2 also, the lightguides 113 are provided in the pixel 101G for green light (“G” in FIG. 2) and the pixel 101R for red light (“R” in FIG. 2), but the lightguide 113 is not provided in each pixel 101B for blue light (“B” in FIG. 2).

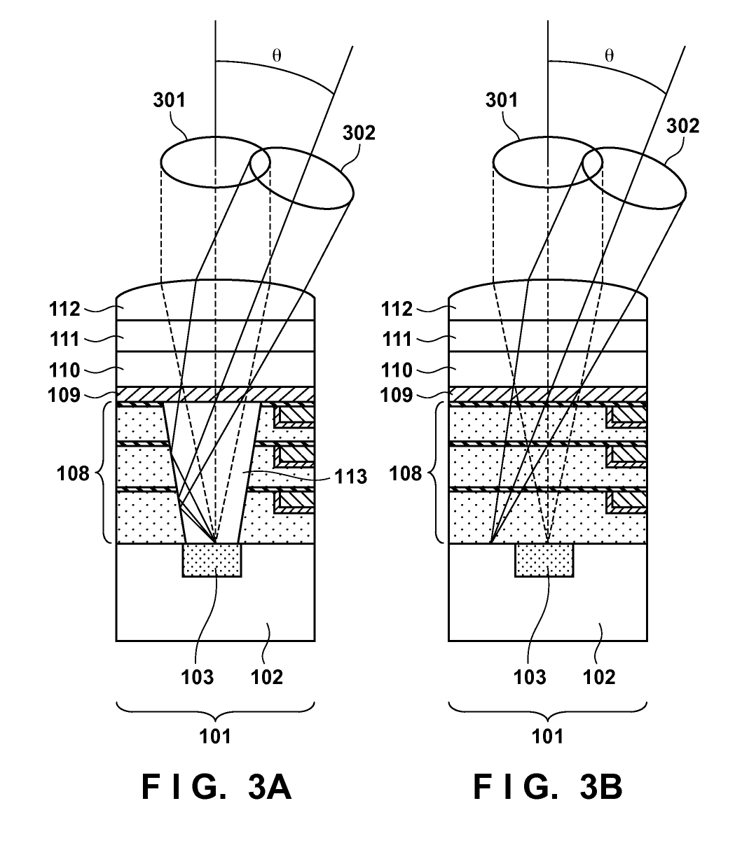

A method of designing the image pickup apparatus 100 will be subsequently described with reference to FIGS. 3A to 5. More specifically, a method of determining which types of pixels 101 should be provided with the lightguides 113 will be described.

First of all, this method determines an arrangement except for the presence/absence of the lightguides 113 of the image pickup apparatus 100. The arrangement to be determined can include, for example, a material for each member, the size of the pixel 101, the type of pixel 101 (for example, the pixel 101G, 101B, or 101R, or the like) to be included in the image pickup apparatus 100, the surface shape of the microlens 112, the thickness of the multilayer wiring layer 108, and the like. These arrangements may be determined by an existing method. Consider, in the following description, a case in which an effective pixel region of the conversion element 103 has a diagonal line length of 1.4 μm.

Subsequently, the arrangement of the lightguide 113 is determined. The arrangement of the lightguide 113 which should be determined can include, for example, a material for the core member of the lightguide 113 and the shape and position of the lightguide 113. The arrangement of the lightguide 113 may be determined by an existing method. In the following description, consider a case in which the lightguide 113 has a circular truncated conical shape, with the height being 1.0 μm, the diameter of the upper circular opening being 0.9 μm, and the diameter of the lower circular portion being 0.74 μm. In addition, silicon dioxide having a refractive index of 1.4 at a wavelength of 550 nm is used as a material for the interlayer dielectric film 104, and silicon nitride having a refractive index of 2.0 at a wavelength of 550 nm is used as a material for the lightguide 113.

Subsequently, the light collection efficiency of each of a plurality of types of pixels 101 is physically optically calculated or measured based on the path of incident light (i.e., the light path) in both cases in which the lightguide 113 is provided and in which the lightguide 113 is not provided. A light collection efficiency can be the ratio of light reaching the conversion element 103 to light reaching the semiconductor substrate 102 upon entering the pixel 101 (more specifically, the microlens 112). A light collection efficiency is determined based on a refractive index and a reflectance without considering the absorption of light by a member configured to transmit light. Since a refractive index and a reflectance can change depending on the wavelength of light, a light collection efficiency may be determined based on each of different wavelengths for the respective types of pixels 101. For example, the light collection efficiency of the pixel 101B for blue light may be determined based on the wavelength band of blue light (e.g., 350 nm to 500 nm). For example, a light collection efficiency may be determined with respect to a representative value (e.g., 400 nm) in this wavelength band. Alternatively, light collection efficiencies may be determined and averaged with respect to a plurality of wavelengths in this wavelength band. The same applies to the pixel 101G for green light and the pixel 101R for red light. In stead of this, a light collection efficiency may be determined under the same condition with respect to all the types of pixels 101.

A model used to determine a light collection efficiency will be described with reference to FIGS. 3A and 3B. FIG. 3A shows light paths when the lightguide 113 is provided in the pixel 101. FIG. 3B shows light paths when the lightguide 113 is not provided in the pixel 101. In each of the cases shown in FIGS. 3A and 3B, a light flux 301 with an incident angle of 0° entirely reaches the conversion element 103. In contrast, in the pixel 101 with the lightguide 113, part of incident light of a light flux 302 with an incident angle θ is reflected by the interface of the lightguide 113 and reaches the conversion element 103. In the pixel 101 without the lightguide 113, part of incident light does not reach the conversion element 103.

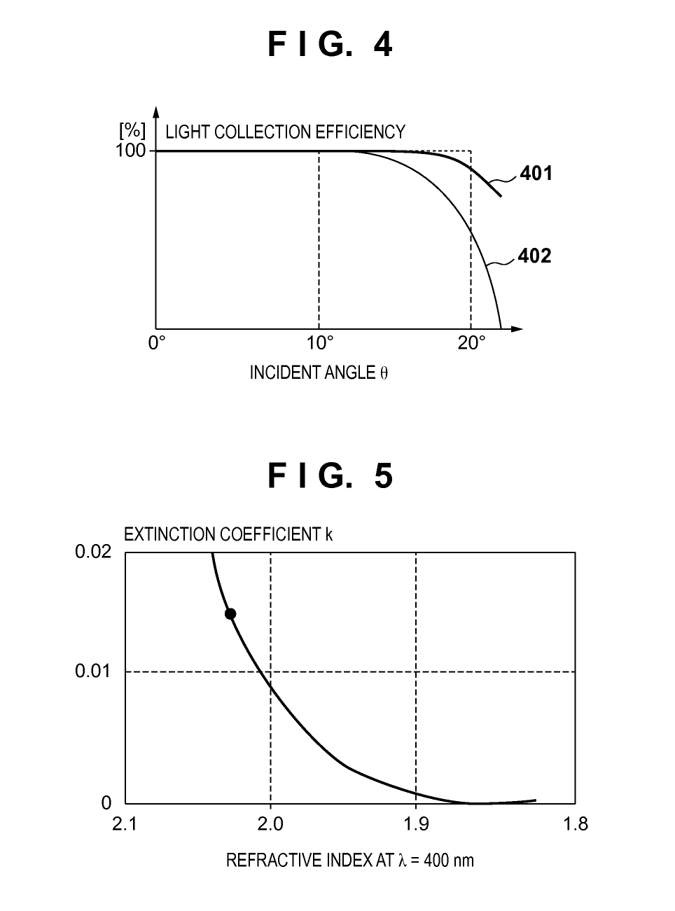

FIG. 4 is a graph showing light collection efficiencies corresponding to various incident angles. In FIG. 4, the abscissa indicates incident angle, and the ordinate indicates light collection efficiency. A curve 401 represents the light collection efficiencies obtained when the lightguide 113 is provided in the pixel 101. A curve 402 represents the light collection efficiencies obtained when the lightguide 113 is not provided in the pixel 101. The curves 401 and 402 overlap in the incident angle range of 0° to about 13°. The curves 401 and 402 are obtained by determining light collection efficiencies from 0° to 20° in increments of 2° and performing curve fitting.

As is obvious from these curves, when the incident angles are small, the light collection efficiency is 100% regardless of the presence/absence of the lightguide 113. However, when the incident angles are large, the light collection efficiencies are higher when the lightguide 113 is provided than when the lightguide 113 is not provided. For example, when the incident angle is 20°, the light collection efficiency is about 90% when the lightguide 113 is provided, and is about 50% when the lightguide 113 is not provided. As shown in FIG. 4, since light collection efficiency depends on incident angle, the average or sum of light collection efficiencies corresponding to incident angles in a predetermined range (e.g., 0° to 20°) may be regarded as a light collection efficiency. For example, light collection efficiencies may be determined by integrating the curves in FIG. 4 in predetermined ranges. In the case shown in FIG. 4, the light collection efficiency improves by about 10% when the lightguide 113 is provided in the pixel 101 as compared with when the lightguide 113 is not provided.

In consideration of only light collection efficiency, a light arrival rate improves when the lightguides 113 are provided in all the types of pixels 101. However, the light transmittance of the lightguide 113 depends on the wavelength of light transmitted through it. In some cases, therefore, a higher light arrival rate is obtained when the lightguide 113 is not provided, depending on the target wavelength for the pixel 101. For example, a light transmittance is given by

light transmittance=exp(−αx) (1)

α=4πk/λ (2)

where α is an absorption coefficient, x is the thickness [μm] of the lightguide 113, k is an extinction coefficient, and λ is the wavelength [μm] of light to be transmitted.

As described above, light transmittance depends on wavelength. For this reason, a light transmittance is determined for each of a plurality of types of pixels. The pixel 101B for blue light will be considered first. The filter 111B of the pixel 101B for blue light transmits light in the wavelength band of 350 nm to 500 nm. Therefore, 400 nm is selected as a representative value, for example. In this case, the refractive index of the lightguide 113 is 2.03. As is obvious from the graph shown in FIG. 5, the extinction coefficient k in this case is 0.015. FIG. 5 is a graph showing the extinction coefficients of materials having various refractive indices with respect to light of a wavelength of 400 nm. This graph is obtained by, for example, experiments. The graph indicates that the extinction coefficient exponentially increases with an increase in refractive index.

Substituting the value determined in the above manner into equations (1) and (2) yields

light transmittance=exp(−0.471)=0.624.

Since the light transmittance of the interlayer dielectric film 104 is about 1, providing the lightguide 113 in the pixel 101B for blue light will decrease the light transmittance by a factor of 0.624.

If a light amount ratio is defined by the product of a collection efficiency and a light transmittance, the ratio of the light amount obtained with the lightguide 113 to the light amount obtained without the lightguide 113 is 1.1×0.624=0.6864. It is therefore obvious that the light amount obtained in the pixel 101B for blue light with the lightguide 113 decreases by about 31% as compared with the light amount obtained without the lightguide 113. For this reason, it is determined that the lightguide 113 should not be provided in the pixel 101B for blue light.

Changes in light amount when the lightguide 113 is provided are determined according to a method similar to that described above with respect to the pixel 101G for green light and the pixel 101R for red light. It is then determined based on this result whether to provide the lightguide 113. In the above case, it is determined that the lightguides 113 should be provided in the pixel 101G for green light and the pixel 101R for red light.

In the above case, a light transmittance is determined based on a representative value in a wavelength band as a detection target for the pixel 101. However, light transmittances may be determined with respect to a plurality of values included in this wavelength band, and the average of the determined values may be determined as the light transmittance of the pixel 101. Alternatively, whether to provide the lightguide 113 having various refractive indices may be determined to determine an optimal arrangement. In addition, the above determination may be performed for some types (e.g., one type) of pixels 101 instead of all the three types of pixels 101. If, for example, it is expected that the pixel 101G for green light and the pixel 101R for red light will exhibit high light transmittances, it may be determined, without performing the above determination, that the lightguides 113 should be provided. Furthermore, the above determination may be repeatedly performed while the shape, position, material, and the like of various lightguides 113 are variously changed.

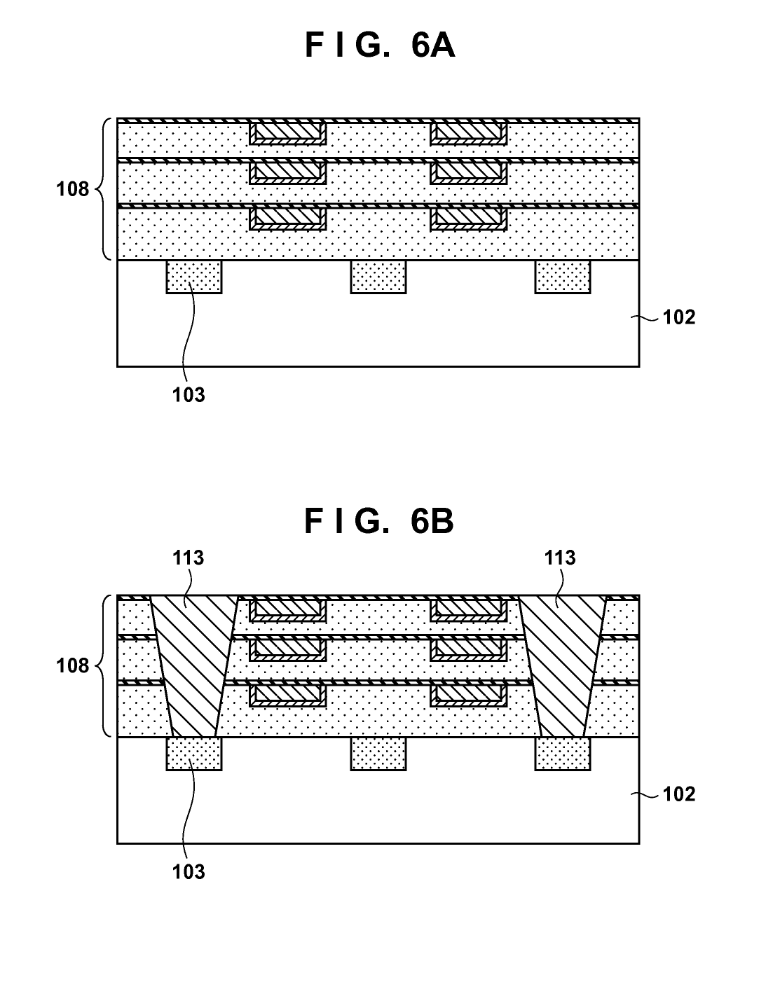

A method of manufacturing the image pickup apparatus 100 will be subsequently described with reference to FIGS. 6A and 6B. FIGS. 6A and 6B show the respective steps in the method of manufacturing the image pickup apparatus 100, and are sectional views each corresponding to the sectional view of FIG. 1. First of all, as shown in FIG. 6A, the multilayer wiring layer 108 is formed on the semiconductor substrate 102 in which the conversion elements 103 are formed. This step can be executed by using an existing technique, and hence a description of it will be omitted.

Subsequently, as shown in FIG. 6B, openings are formed, above the conversion elements 103, in the types of pixels 101 determined, by the above design method, as pixels which should be provided with the lightguides 113, by anisotropic etching. Thereafter, silicon nitride is deposited by plasma CVD to bury the openings with the silicon nitride. This forms the lightguides 113. Adjusting deposition conditions when using plasma CVD can control the refractive index of the silicon nitride of the lightguides 113.

Subsequently, the passivation film 109, the planarization resin layer 110, the filters 111B, 111G, and 111R, and the microlenses 112 are formed on the multilayer wiring layer 108, thereby obtaining the structure shown in FIG. 1. An existing technique can be used for this step, and hence a description of it will be omitted.

The above embodiment has exemplified the case in which the pixels 101 are classified into three types (i.e., pixels for green light, blue light, and red light). However, the present invention can be applied to a case in which the pixels 101 are classified into two or more types. For example, the plurality of pixels of the image pickup apparatus 100 can include a pixel for detecting infrared light in addition to the above three types of pixels. This pixel for detecting infrared light can be provided with a filter configured to transmit infrared light. In addition, the above pixels can include a pixel for detecting ultraviolet light in addition to the above three types of pixels. This pixel for detecting ultraviolet light can be provided with a filter configured to transmit ultraviolet light. The above design method can also be applied to these pixels. For example, if silicon nitride is used as a material for the lightguide 113, the absorbance is high in the wavelength band of 350 nm to 450 nm and in the wavelength band of infrared light. It can therefore be determined that the lightguide 113 should be provided in a pixel for detecting infrared light, whereas the lightguide 113 should not be provided in a pixel for detecting ultraviolet light.

In the above embodiment, the visible light region (e.g., the wavelength band of 400 nm to 800 nm) is covered by three types (three colors) of pixels. However, the visible light region may be covered by four or more types of pixels. If silicon nitride is used as a material for the lightguide 113, silicon nitride has a high absorbance of light in the wavelength band of 350 nm to 450 nm. For this reason, it can be determined, as a result of using the above design method, that the lightguide 113 should not be provided in the type of pixel which covers this wavelength band, but the lightguides 113 should be provided in other types of pixels. In the above embodiment, silicon nitride is used as a core material for the lightguide 113. Instead of this, however, the material obtained by dispersing a titanium-based metal filler in a siloxane-based resin may be used. Using this material will also decrease the transmittance of light in a specific wavelength band. Therefore, the above design method can be used.

In the above embodiment, the anti-diffusion layer 107 is provided on the conversion element 103 of the pixel 101B for blue light. Since the anti-diffusion layer 107 is only required to be provided so as to cover the wiring pattern 105, the anti-diffusion layer 107 on the conversion element 103 may be removed. This arrangement can reduce reflection on the interface of the anti-diffusion layer 107 which is caused by the presence of the film.

A camera incorporating the image pickup apparatus will be exemplified as an application of the image pickup apparatus according to each embodiment described above. The concept of a camera includes not only an apparatus mainly aimed at imaging but also an apparatus including an image pickup function as an auxiliary function (for example, a personal computer or a portable terminal). The camera includes the image pickup apparatus according to the present invention, which has been exemplified as the above embodiments and a processing unit which processes the signal output from the image pickup apparatus. This processing unit can include, for example, an A/D converter and a processor which processes the digital data output from the A/D converter.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-131056, filed Jun. 21, 2013 which is hereby incorporated by reference herein in its entirety.

What is claimed is:

1. An image pickup apparatus including a plurality of types of pixels,
each of said plurality of types of pixels comprising
a conversion element configured to convert light into a charge, and
one of a plurality of types of filters configured to transmit light in different wavelength bands, wherein
a first type of pixel of said plurality of types of pixels further includes a lightguide configured to guide light entering said pixel to said conversion element, and
a second type of pixel of said plurality of types of pixels includes no structure corresponding to said lightguide.

2. The apparatus according to claim 1, wherein said lightguide comprises a core member, and
a cladding member having a lower refractive index than said core member is provided around said core member.

3. The apparatus according to claim 2, wherein the cladding member includes an interlayer dielectric film.

4. The apparatus according to claim 2, wherein said core member comprises silicon nitride.

5. The apparatus according to claim 1, wherein a transmittance when light in a wavelength band as a detection target for said first type of pixel passes through said lightguide is higher than a transmittance when light in a wavelength band as a detection target for said second type of pixel passes through said lightguide.

6. The apparatus according to claim 1, wherein said plurality of types of pixels include a pixel for detecting green light, a pixel for detecting blue light, and a pixel for detecting red light, and
said pixel for detecting green light is said first type of pixel,
said pixel for detecting red light is said first type of pixel, and
said pixel for detecting blue light is said second type of pixel.

7. The apparatus according to claim 6, wherein said plurality of types of pixels further include a pixel for detecting infrared light, and
said pixel for detecting infrared light is said second type of pixel.

8. The apparatus according to claim 1, wherein each of said plurality of types of pixels further includes a microlens configured to condense incident light in said conversion element.

9. The apparatus according to claim 1, wherein said first type of pixel is a pixel which is provided with a lightguide which guides light entering said pixel to said conversion element to increase an amount of light reaching said conversion element more than when the pixel is not provided with said lightguide, and
said second type of pixel is a pixel which is not provided with a structure corresponding to a lightguide which guides light entering said pixel to said conversion element to increase an amount of light reaching said conversion element more than when the pixel is provided with the structure.

10. A method of designing an image pickup apparatus including a plurality of types of pixels,
each of the plurality of types of pixels comprising
a conversion element configured to convert light into a charge, and
one of a plurality of types of filters configured to transmit light in different wavelength bands, and
the method comprising determining, for each of the plurality of types of pixels, whether an amount of light reaching the conversion element increases more when a lightguide which guides light entering the pixel to the conversion element is provided than when the lightguide is not provided.

11. The method according to claim 10, wherein the determining comprises determining whether the amount of light increases, based on a change in transmittance with respect to incident light when the lightguide is provided and a change in light path of incident light when the lightguide is provided.

12. The method according to claim 11, wherein the change in transmittance is determined for light in a wavelength band as a detection target for the pixel.

13. The method according to claim 11, wherein the change in light path is determined with respect to a plurality of incident angles of light entering the pixel.

14. A method of manufacturing an image pickup apparatus including a plurality of types of pixels, said method comprising forming the lightguide in a pixel determined as a pixel in which a light amount is increased by a design method defined in claim 10.
